(19) United States
(12) Patent Application Publication
(10) Pub. No.: US 2008/0197877 A1
(43) Pub. Date: Aug. 21, 2008

(54) Per byte lane dynamic on-die termination

(75) Inventors: Christopher E. Cox, Placerville, CA (US); Hany Fahmy, Elk Grove, CA (US); Hideo Oie, Folsom, CA (US)

Correspondence Address: INTEL CORPORATION;c/o INTELLEVATE, LLC, P.O. BOX 52050, MINNEAPOLIS, MN, 55402, US

(73) Assignee: INTEL CORPORATION

(21) Appl. No.: 11/708,148

(22) Filed: Feb. 16, 2007

(51) Int. Cl. H03K 19/173

(52) U.S. Cl. 326/38

(57) ABSTRACT

Embodiments of the invention are generally directed to systems, methods, and apparatuses for per byte lane dynamic on-die termination. In some embodiments, an integrated circuit includes logic to independently program at least one on-die termination (ODT) value for each of a plurality of integrated circuits coupled together through an interconnect. Other embodiments are described and claimed.

### TECHNICAL FIELD

Embodiments of the invention generally relate to the field of integrated circuits and, more particularly, to systems, methods and apparatuses for per byte lane dynamic on-die termination.

### BACKGROUND

The operating frequencies of integrated circuits such as memory devices are progressively increasing. To take advantage of these high frequencies computing systems are designed to transmit signals along their busses and between system components at comparable frequencies.

Some difficulties may be encountered when transmitting and receiving data between system components (e.g., between integrated circuits) at high frequencies. Buses behave like transmission lines, where impedance mismatches lead to signal reflection and interference effects. Termination resistance can be used to maintain signal quality over interconnections by matching impedances to minimize signal reflections.

Conventional memory systems, such as double data rate (DDR) dynamic random access memory devices (DRAMs) typically have multi-drop bus architectures that are terminated with a resistor that is resident on the motherboard. In other conventional memory systems, the termination resistor is resident on the integrated circuit.

The term “on-die termination (ODT)” refers to termination resistance that is resident on the integrated circuit. In conventional systems, the value of ODT is set when a computing system is initialized. After initialization, the ODT can be activated or deactivated with the value that is set during initialization.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a high-level block diagram illustrating selected aspects of a computing system implemented according to an embodiment of the invention.

FIG. 2 is a high-level block diagram illustrating selected aspects of a computing system implemented according to an embodiment of the invention.

FIG. 3 is a block diagram illustrating selected aspects of a computing system implemented according to an embodiment of the invention.

FIG. 4 is a high-level flow diagram illustrating selected aspects of programming DRAMs with ODT values, according to an embodiment of the invention.

FIG. 5 is a conceptual diagram illustrating selected aspects of individually programming DRAMs with ODT values, according to an embodiment of the invention.

FIG. 6 is a flow diagram illustrating selected aspects of per byte lane termination, according to an embodiment of the invention.

FIGS. 7A and 7B are block diagrams illustrating selected aspects of computing systems.

### DETAILED DESCRIPTION

Embodiments of the invention are generally directed to systems, methods, and apparatuses for per byte lane on-die termination (ODT). Each of a plurality of integrated circuits (e.g., memory devices) connected to an interconnect (e.g., a data bus) may support dynamic ODT. In some embodiments, each integrated circuit (IC) is capable of individually switching between multiple distinct, predetermined ODT values (e.g., from 20-120 Ohms). The ODT values may be switched as appropriate to support nearly any operation (e.g., active/passive states, reads/writes, etc.). In some embodiments directed to memory systems, the write capability of the multipurpose register (MPR) may be used to individually program ODT values to each DRAM. Such embodiments of the invention may enable, for example, the use of two memory modules on a memory channel including four ranks at speeds greater than 1066 MT/s.

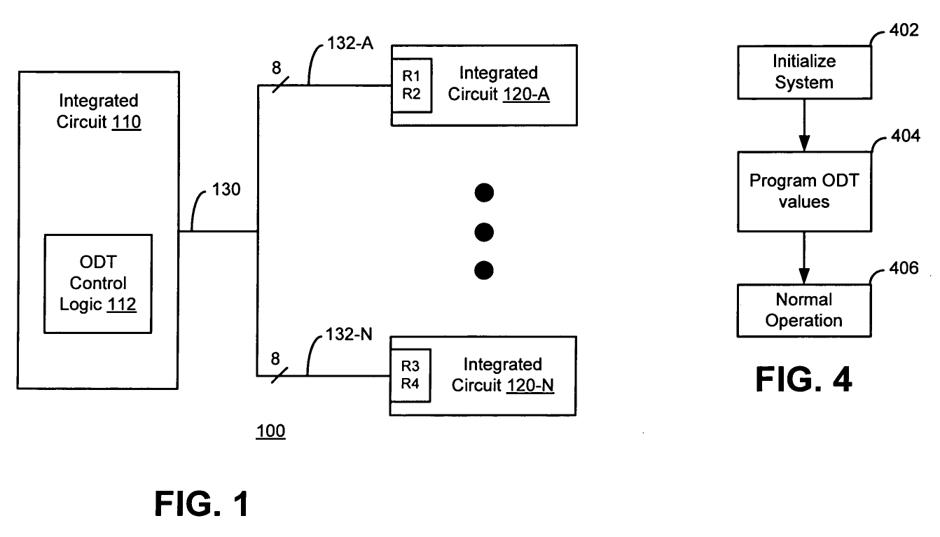

FIG. 1 is a high-level block diagram illustrating selected aspects of a computing system implemented according to an embodiment of the invention. System 100 includes integrated circuit 110 (e.g., a controller such as a memory controller) coupled with integrated circuits 120 over interconnect 130. In some embodiments, interconnect 130 is composed of a number of byte lanes 132. A byte lane refers to an 8-bit portion of a channel that may be greater than 8 bits in width (e.g., an 8-bit portion of a 64-bit memory channel).

It is to be appreciated that the routing lengths for each byte lane may vary based on a number of factors. For example, the routing lengths may vary for each different form factor using system 100. The impedance of each byte lane varies as a function of the length of the byte lane. A preferred termination value (RTT) for each integrated circuit 120 may depend, in part, on the impedance of the byte lane.

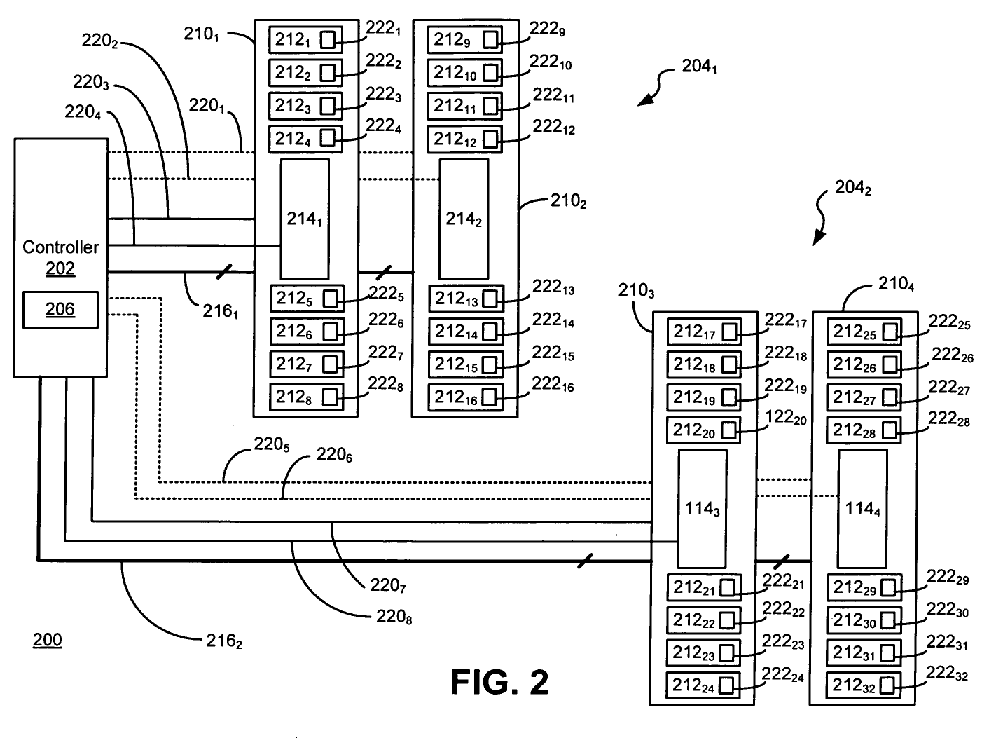

Integrated circuit 110 includes, inter alia, ODT control logic 112. In some embodiments, ODT control logic 112 is capable of individually controlling the ODT value for each byte lane 132 (and, correspondingly, for each integrated circuit 120). This enables ODT control logic 112 to enhance the performance of a high speed interconnect (e.g., interconnect 130) even if the lengths of byte lanes 132 are different, for example, for each form factor. Selected aspects of ODT control logic and per byte lane termination are further discussed below, with reference to FIGS. 2-8. For ease of discussion, embodiments of the invention are discussed with reference to a memory system. It is to be appreciated, however, that embodiments of the invention are not limited to memory systems.

FIG. 2 is a high-level block diagram illustrating selected aspects of a computing system implemented according to an embodiment of the invention. Computing system 200 includes controller 202 and two memory channels 204. Controller 202 may be any type of controller suitable for controlling, at least in part, the transfer of information between a processor (not shown) and one or more integrated circuits (e.g., memory devices). In some embodiments, controller 202 is a memory controller. Controller 202 includes on-die termination (ODT) control logic 206. As is further described below, in an embodiment, ODT control logic 206 determines one or more appropriate ODT values for at least some of the integrated circuits in system 200.

Memory channels 204 include memory modules 210 each having, for example, two ranks of memory devices (e.g., one on either side). Memory modules 210 may be based on printed circuit boards having fingers along both sides of one edge to create a dual inline memory module (DIMM) that may be plugged into a connector on another circuit board that holds other components of the system. Modules 210 are populated with memory devices 212. The memory devices may be commodity-type dynamic random access memory (DRAM) such as double data rate (DDR) DRAM. In an embodiment, each module 210 includes two ranks (e.g., one on each side of the module). Registers 214 may receive and store information for a corresponding rank.

In an embodiment, controller 202 is coupled with modules 210 via interconnect 216. Interconnect 216 may include an arbitrary number of data lines, address lines, chip select lines and/or other lines. In addition, memory controller 202 is coupled with each rank via on-die termination (ODT) lines 220. In an embodiment, ODT lines 220 provide ODT activation signals for memory devices 212. An ODT activation signal refers to a signal that activates ODT for an integrated circuit or a group of integrated circuits. As is further discussed below, ODT lines 220 may also provide an ODT value selection signal for memory devices 212. An ODT value selection signal refers to a signal that indicates a desired ODT value. In some embodiments, the ODT activation signal activates ODT for an entire rank of memory devices 212. Similarly, in some embodiments, the ODT value selection signal selects an ODT value for an entire rank of memory devices 212. In such embodiments, the ODT pins for the memory devices within a rank may be daisy-chained together so that the same ODT signals (e.g., ODT activation signals and ODT value selection signals) are routed to the memory devices within the rank. As is further discussed below, however, the particular ODT values used by each individual memory device 212 may be different. That is, the ODT value selection signals may instruct all of the memory devices within a rank to use a primary ODT value but the particular primary ODT value used by each memory device may be different (depending, for example, on the length of the byte lane corresponding to the memory device).

The number of memory channels, memory modules, and memory devices shown in FIG. 2 are for illustrative purposes. An embodiment of the invention may have a different number of memory channels, a different number of memory modules, and/or a different number of memory devices. In addition, the topology and architecture illustrated in FIG. 2 are for illustrative purposes. An embodiment of the invention may have a different topology and/or different architectural features.

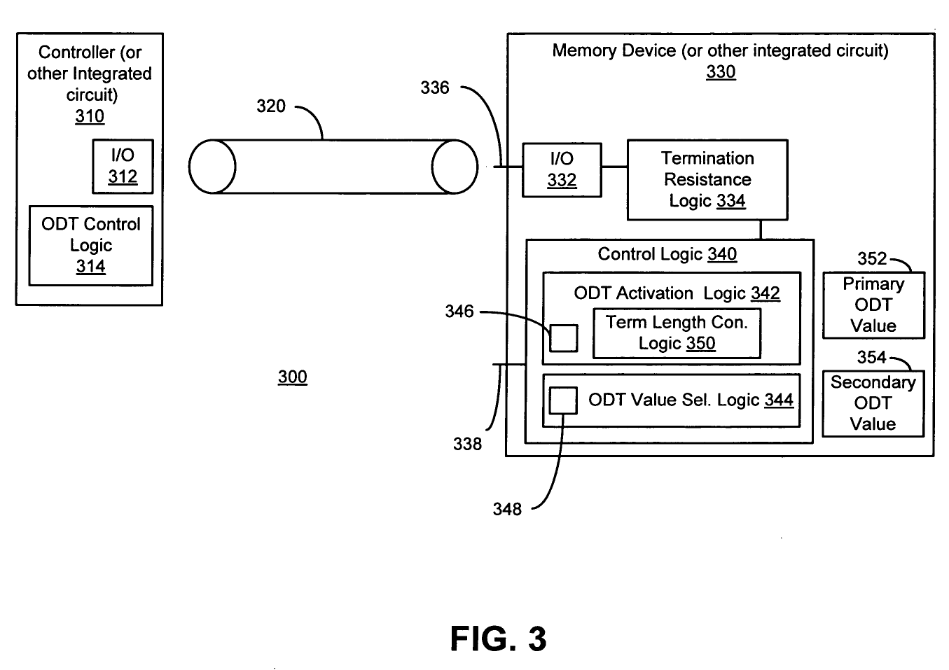

FIG. 3 is a block diagram illustrating selected aspects of a computing system implemented according to an embodiment of the invention. Computing system 300 includes memory controller 310 and memory device 330 coupled together by interconnect 320. In some embodiments, memory controller 310 is part of the chipset for computing system 300 and memory device 330 is part of the memory subsystem for computing system 300. Memory device 330 may be a DRAM such as a DDR3 synchronous DRAM (SDRAM). Interconnect 320 broadly represents, for example, a number of different data lines, address lines, control lines, and the like.

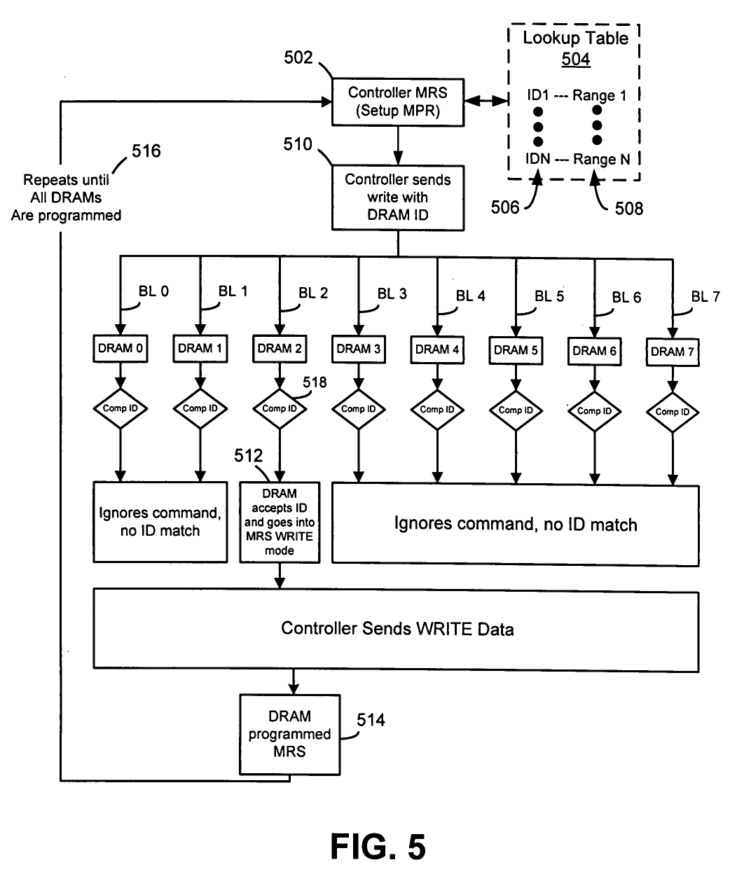

Memory controller 310 includes input/output (I/O) circuit 312 and ODT control logic 314. I/O circuit 312 can be any I/O circuit suitable for transmitting and receiving information (e.g., data, ODT signals, addresses, etc.) with memory device 330. In some embodiments, ODT control logic 314 individually determines one or more appropriate ODT values for memory device 330. For example, ODT control logic 314 may dynamically determine appropriate ODT values for memory device 330 to use during both read and write operations. As is further discussed below, with reference to FIGS. 5-7, control logic 314 may program the appropriate ODT values into memory device 330 during, for example, an initialization process (such as boot up).

Memory device 330 includes I/O circuit 332, termination resistance logic 334, and control logic 340. I/O circuit 332 may be any I/O circuit suitable for transmitting and receiving information (e.g., data, ODT signals, addresses, etc.) with memory controller 310. In some embodiments, termination resistance logic 334 includes a plurality of termination legs that can be selectively activated to dynamically provide a plurality of termination resistances for I/O circuit 332.

Memory device 330 is coupled to interconnect 320 through a plurality of pins including, for example, pins 336 and 338. The term “pin” broadly refers to an electrical interconnection for an integrated circuit (e.g., a pad or other electrical contact on the integrated circuit). For ease of description, FIG. 3 illustrates an individual pin 336 but it is to be appreciated that, typically, a plurality of pins are used to convey data, addresses, commands (e.g., read/write pins), and the like. In an embodiment, pin 338 is an ODT pin. An ODT pin refers to a pin that, in some conventional systems, receives an ODT activation signal.

In an embodiment, control logic 340 enables two or more signals to be multiplexed (e.g., time multiplexed) on ODT pin 338. For example, in some embodiments, control logic 340 enables an ODT activation signal and an ODT value selection signal to be multiplexed on ODT pin 338. In some embodiments, control logic 340 may recognize and latch each of the different signals that are multiplexed on ODT pin 338. The latch(es) may stay set for a defined period of time (e.g., a certain number of clock cycles) to deny a reset of the state of the latches by, for example, controller 310. After the defined length of time, control logic 340 may allow a reset of the state to return control of the ODT pin to controller 310.

In some embodiments, control logic 340 includes ODT activation logic 342 and ODT value selection logic 344. ODT activation logic 342 detects an ODT activation signal on ODT pin 338 and activates termination resistance logic 334 responsive to receiving the ODT activation signal. In some embodiments, ODT activation logic 342 includes latch 346. Latch 346 recognizes and latches ODT activation signals that are received on ODT pin 338. Latch 346 may stay set for a defined period of time after it detects an ODT activation signal. For example, in some embodiments, latch 346 stays set for two clock cycles after it detects an ODT activation signal. Since latch 346 stays set for a defined length of time, additional signals (e.g., an ODT value selection signal) may be received on ODT pin 338 without resetting the ODT activation signal. In some embodiments, the period of time that latch 346 stays set may be configurable (e.g., by setting a value in a value in a register).

In some embodiments, memory device 330 is capable of determining when to deactivate its ODT (e.g., when to deactivate termination resistance logic 334). The term “length of termination” broadly refers to the amount of time that the ODT is activated. The illustrated embodiment of ODT activation logic 342 includes termination length control logic 350. Termination length (TL) control logic 350 determines an appropriate length of termination for the ODT provided by termination resistance logic 334.

In some embodiments, TL control logic 350 determines the length of termination based, at least in part, on a command (e.g., a read or write command) received from controller 310. For example, in some embodiments, TL control logic 350 decodes (or partly decodes) the received command and determines a burst length associated with the command. TL control logic 350 may then determine a termination length based, at least in part, on the burst length. For example, the length of termination may be based, at least in part, on the expression: BL/M+N (where BL is the burst length of the associated command). In some embodiments, M and N are both equal to two. In alternative embodiments, the length of termination may be based on a different expression and/or the values of M and/or N may be different.

In some embodiments, TL control logic 350 deactivates the ODT subsequent to the expiration of the length of termination. Control logic 340 may then return control of the ODT to controller 310. Returning control of the ODT to controller 310 may include, for example, allowing latches 346 and 348 to be set/reset by controller 310.

ODT value selection logic 344 detects an ODT value selection signal on ODT pin 338 and then sets the resistance level of termination resistance logic 334 based (at least partly) on the received ODT value selection signal. Registers 352 and 354 may be configured, respectively, with a primary and a secondary ODT value during, for example, system initialization. In some embodiments, ODT control logic 314 individually configures registers 352 and 354 with ODT values that are specific for each memory device 330. ODT value selection logic 344 may then select an ODT value from either register 352 or 354 based on the received ODT value selection signal. For example, if the ODT value selection signal is high (logically), then ODT value selection logic 344 may select a value from register 352. Similarly, if the ODT value selection signal is low, then ODT value selection logic 344 may select a value from register 354. In some embodiments, ODT value selection logic 344 includes latch 348. Latch 348 recognizes and latches ODT value selection signals that are received on ODT pin 338. Latch 348 may stay set for a defined period of time after it detects an ODT value selection signal.

FIG. 4 is a high-level flow diagram illustrating selected aspects of programming DRAMs with ODT values, according to an embodiment of the invention. A computing system (e.g., system 200, shown in FIG. 2) is initialized at 402. Initializing the computing system may include booting the system, powering-up the system from a low power state, resetting the system (or a portion of the system), and the like.

Referring to process block 404, the ODT values for each DRAM are programmed. In some embodiments, the computing system's basic input/output system (BIOS) manages aspects of the initialization. In other embodiments, the computing system's memory controller manages aspects of the initialization process. The process of programming the ODT values for each DRAM may include individually setting ODT values in one or more registers of each DRAM in the memory system. For example, the ODT values may be sequentially written to each DRAM as is further described below with reference to FIG. 5.

The computing system begins normal operation at 406. For example, read and write operations may be issued to the memory devices. In some embodiments, each memory device is capable of applying different termination values to the data bus during the read and write operations.

FIG. 5 is a conceptual diagram illustrating selected aspects of individually programming DRAMs with ODT values, according to an embodiment of the invention. In some embodiments, controller 502 knows which byte lanes (BLs) are grouped together into which byte lane length ranges. For example, controller 502 may know that BL 0 and BL 1 have the shortest length range (e.g., 2.5-3.5 inches). Similarly, controller 502 may know that BL 6 and BL 7 have the longest length range (e.g., 4-5 inches). In some embodiments, the controller knows this based on, for example, design guidelines for the system.

Each DRAM may have a DRAM identifier (DRAM ID) that corresponds to the length of its corresponding byte lane. In some embodiments, controller 502 assigns the DRAM IDs to the DRAMs based, for example, on lookup table 504. Lookup table 504 may include a number of DRAM IDs 506 and their corresponding byte lane length ranges 508. In some embodiments, controller 502 serially writes the appropriate DRAM ID into a register (e.g., the MPR) of each DRAM.

Subsequent to assigning the DRAM IDs, controller 502 may send data to, the entire rank of memory. The data may include a particular DRAM ID (e.g., the DRAM ID corresponding to BL 2 in the illustrated embodiment) and ODT values corresponding to the DRAM ID as shown by block 510. The data may be sent in more than one write cycle (e.g., a first write cycle for the DRAM ID and a second write cycle for the ODT values). Each DRAM may compare the received DRAM ID with the DRAM ID that it previously stored. In some embodiments, if the received DRAM ID matches the stored DRAM ID, then the DRAM accepts the ODT values (e.g., 514). The process may be repeated until the ODT values for each DRAM are independently programmed (e.g., 516).

In some embodiments, the write capability of the MPR is used to individually program the ODT values into each DRAM. For example, a DRAM might only go into the mode register set (MRS) write mode, if a comparator (e.g., 518) matches a received DRAM ID with an internally stored DRAM ID. In some embodiments, MRS would include an enhancement in which two write cycles would follow the MRS command. The first write cycle may include a DRAM ID and the second write cycle may include the corresponding ODT values.

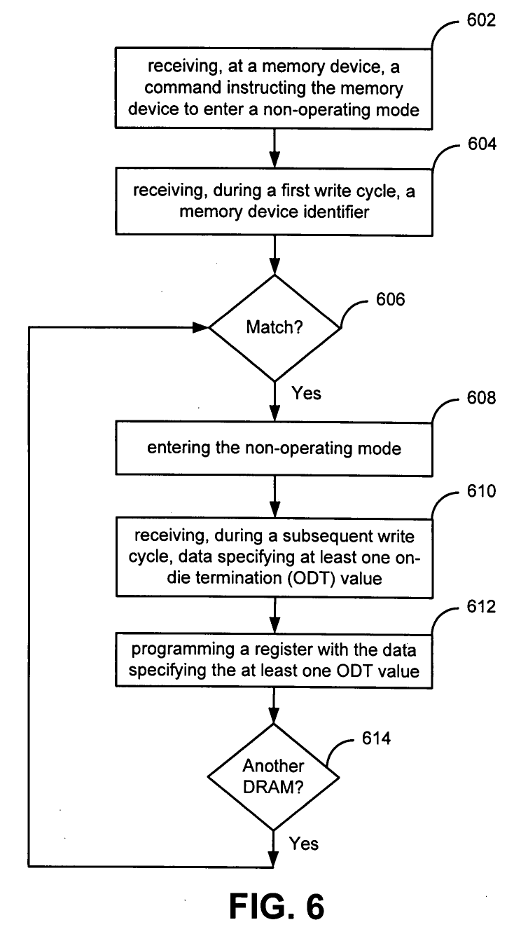

FIG. 6 is a flow diagram illustrating selected aspects of per byte lane termination, according to an embodiment of the invention. Referring to process block 602, a memory device (e.g., a DRAM) receives a command instructing the device to enter a non-operating mode. In some embodiments, the command is an MRS command and the non-operating mode is the MRS write mode. In alternative embodiments, different commands and/or non-operating modes may be used.

The memory device receives an ID at 604 during a first write cycle. The memory device compares the received ID with a previously stored ID at 606. If the received ID matches the previously stored ID, then the memory device enters the non-operating mode (e.g., the MRS write mode) at 608.

Referring to process block 610, the memory device receives, during a subsequent write cycle, data specifying at least one ODT value. In some embodiments, the memory device receives two or more ODT values that can be used to set different termination values for different states (e.g., active/passive) and/or for different operations (e.g., reads/writes). The ODT values are written into one or more registers on the memory device at 612. In some embodiments, the ODT values are written into the memory device's MPR. In alternative embodiments, a different register may be used. The process may be repeated for each DRAM as shown by 614.

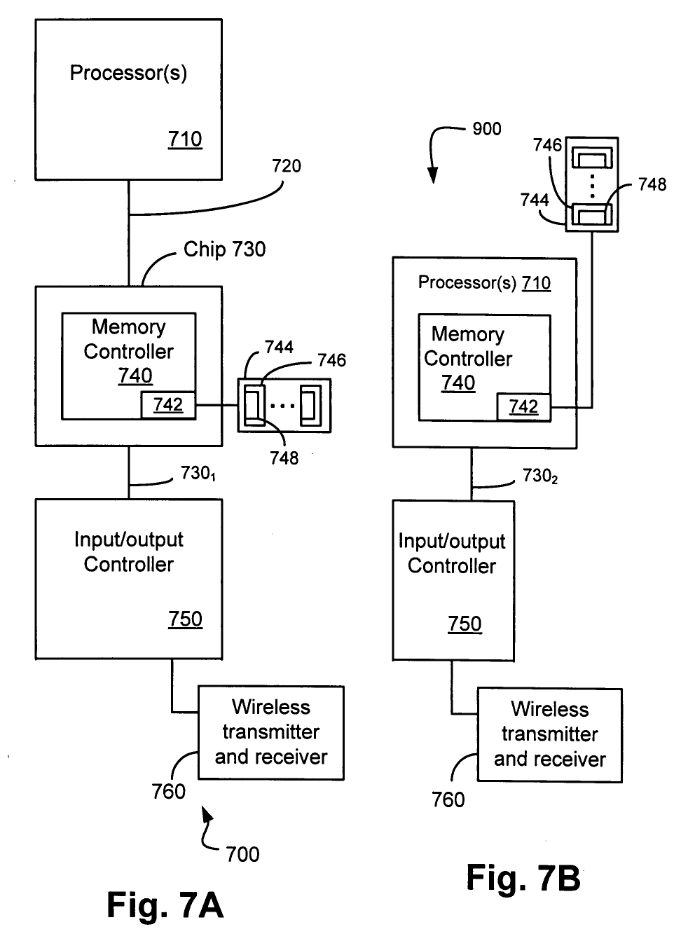

FIGS. 7A and 7B are block diagrams illustrating, respectively, selected aspects of computing systems 700 and 800. Computing system 700 includes processor 710 coupled with an interconnect 720. In some embodiments, the term processor and central processing unit (CPU) may be used interchangeably. In one embodiment, processor 710 is a processor in the XEON® family of processors available from Intel Corporation of Santa Clara, Calif. In an alternative embodiment, other processors may be used. In some embodiments, processor 710 may include multiple processor cores.

In one embodiment, chip 730 is a component of a chipset. Interconnect 720 may be a point-to-point interconnect or it may be connected to two or more chips (e.g., of the chipset). Chip 730 includes memory controller 740 which may be coupled with main system memory (e.g., as shown in FIG. 1). In an alternative embodiment, memory controller 740 may be on the same chip as processor 710 as shown in FIG. 7B.

Memory system 744 may provide main memory for computing system 700 (and computing system 800). In some embodiments, each memory device 746 within memory system 744 includes control logic 748. Control logic 748 enables memory device 746 to multiplex two or more signals on, for example, an ODT pin. In addition, memory controller 740 may include ODT control logic 742. In some embodiments, ODT control logic 742 enables memory controller 740 to individually determine an appropriate ODT value for the memory devices in memory system 744.

Input/output (I/O) controller 750 controls the flow of data between processor 710 and one or more I/O interfaces (e.g., wired and wireless network interfaces) and/or I/O devices. For example, in the illustrated embodiment, I/O controller 750 controls the flow of data between processor 710 and wireless transmitter and receiver 760. In an alternative embodiment, memory controller 740 and I/O controller 750 may be integrated into a single controller.

Elements of embodiments of the present invention may also be provided as a machine-readable medium for storing the machine-executable instructions. The machine-readable medium may include, but is not limited to, flash memory, optical disks, compact disks-read only memory (CD-ROM), digital versatile/video disks (DVD) ROM, random access memory (RAM), erasable programmable read-only memory (EPROM), electrically erasable programmable read-only memory (EEPROM), magnetic or optical cards, propagation media or other type of machine-readable media suitable for storing electronic instructions. For example, embodiments of the invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

Similarly, it should be appreciated that in the foregoing description of embodiments of the invention, various features are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed subject matter requires more features than are expressly recited in each claim. Rather, as the following claims reflect, inventive aspects lie in less than all features of a single foregoing disclosed embodiment. Thus, the claims following the detailed description are hereby expressly incorporated into this detailed description.

What is claimed is:

1. An integrated circuit comprising:
logic to independently program at least one on-die termination (ODT) value for each of a plurality of integrated circuits coupled together through an interconnect, wherein the ODT value specifies an amount of termination resistance.

2. The integrated circuit of claim 1, wherein the plurality of integrated circuits comprises:
a plurality of dynamic random access memory device (DRAM) in a memory system.

3. The integrated circuit of claim 2, wherein the logic to independently program at least one ODT value for each DRAM in the memory system comprises:
logic to determine a specific DRAM identifier for each DRAM in the memory system, wherein the DRAM identifier corresponds to a range of byte lane lengths; and
logic to program the specific DRAM identifier into a register of each DRAM in the memory system.

4. The integrated circuit of claim 3, wherein the logic to determine a specific DRAM identifier for each DRAM in the memory system comprises:
a lookup table specifying a plurality of DRAM identifiers and a corresponding plurality of ranges of byte lane lengths.

5. The integrated circuit of claim 2, wherein the logic to independently program at least one ODT value for each DRAM in the memory system comprises:
logic to issue a command for each DRAM to enter a non-operating mode;
logic to send, during a first write cycle, a DRAM identifier; and
logic to send, during a second write cycle, at least one ODT value corresponding to the DRAM identifier.

6. The integrated circuit of claim 5, wherein
the command is a mode register set (MRS) command and the non-operating mode is an MRS WRITE mode.

7. The integrated circuit of claim 6, wherein the logic to send, during the second write cycle, at least one ODT value corresponding to the DRAM identifier comprises:
logic to send a first ODT value and a second ODT value, wherein the first ODT value corresponds to an active state and the second ODT value corresponds to a passive state.

8. The integrated circuit of claim 1, wherein the integrated circuit comprises a memory controller.

9. The integrated circuit of claim 8, wherein the integrated circuit further comprises a processor.

10. A method comprising:
receiving, at a memory device, a command instructing the memory device to enter a non-operating mode;
receiving, during a first write cycle, a memory device identifier;
comparing the received DRAM identifier with a stored value; and
entering the non-operating mode, if the received memory device identifier matches the stored value.

11. The method of claim 10, further comprising:
receiving at the memory device, during a subsequent write cycle, data specifying at least one on-die termination (ODT) value; and
programming a register with the data specifying the at least one ODT value.

12. The method of claim 11, wherein the memory device is a dynamic random access memory device (DRAM).

13. The method of claim 12, wherein the command is a mode register set (MRS) command.

14. The method of claim 13, wherein the register is a multipurpose register (MPR).

15. A system comprising:
a plurality of memory devices coupled with an interconnect; and
an integrated circuit coupled with the interconnect, the integrated circuit including logic to independently program at least one on-die termination (ODT) value for each of a plurality of the plurality of memory devices, wherein the ODT value specifies an amount of termination resistance.

16. The system of claim 15, wherein the plurality of memory devices is a plurality of dynamic random access memory devices (DRAMs).

17. The system of claim 15, wherein the logic to independently program at least one ODT value for each DRAM comprises:
logic to determine a specific DRAM identifier for each DRAM in the memory system, wherein the DRAM identifier corresponds to a range of byte lane lengths; and
logic to program the specific DRAM identifier into a register of each DRAM in the memory system.

18. The system of claim 17, wherein the logic to determine a specific DRAM identifier for each DRAM in the memory system comprises:
a lookup table specifying a plurality of DRAM identifiers and a corresponding plurality of ranges of byte lane lengths.

19. The system of claim 16, wherein the logic to independently program at least one ODT value for each DRAM in the memory system comprises:
logic to issue a command for each DRAM to enter a non-operating mode;
logic to send, during a first write cycle, a DRAM identifier; and
logic to send, during a second write cycle, at least one ODT value corresponding to the DRAM identifier.

20. The system of claim 19, wherein
the command is a mode register set (MRS) command and the non-operating mode is an MRS WRITE mode.
